(19) United States
(12) Patent Application Publication
(10) Pub. No.: US 2025/0162217 A1
(43) Pub. Date: May 22, 2025

(54) METHOD FOR PRODUCING AN ELECTRONIC COMPONENT

(71) Applicant: Thomas Magnete GmbH, Herdorf (DE)

(72) Inventors: Robert HEINZ, Hachenburg (DE); Sebastian EMDE, Siegen (DE); Sebastian WEBER, Wetzlar (DE)

(73) Assignee: Thomas Magnete GmbH, Herdorf (DE)

(21) Appl. No.: 18/839,201

(22) PCT Filed: Feb. 13, 2023
(86) PCT No.: PCT/DE2023/100114

§ 371 Date: Aug. 16, 2024

(30) Foreign Application Priority Data
Feb. 18, 2022 (DE) 10 2022 103 918.8

(51) Int. Cl. B29C 45/14; B29C 45/16; B29L 31/34

(52) U.S. Cl. CPC B29C 45/14639; B29C 45/1671; B29C 2045/1673; B29L 2031/3481

(57) ABSTRACT

A process for producing an electronic component, which has at least one electromagnetic actuator and an electronics unit, wherein the process comprises a first overmolding of the electronics unit with a first plastic to produce a first sheath of the electronics unit, and a second overmolding of the first sheath together with the electromagnetic actuator to produce a second sheath of the electronics unit and of the electromagnetic actuator, wherein the first plastic is injection molded with a lower temperature and/or a lower pressure than the second plastic, the first overmolding is carried out such that the first sheath encloses the electronics unit such that, during the second overmolding, the second sheath does not make contact with the electronics unit, and the second overmolding is carried out such that the electromagnetic actuator and the electronics unit with the first sheath are media-tightly enclosed by the second sheath.

### CROSS REFERENCE TO RELATED APPLICATIONS

This application is a National Stage of International Application No. PCT/DE2023/100114, filed Feb. 13, 2023, which claims the benefit of and priority to German Patent Application DE 102022103918.8, filed Feb. 18, 2022. The entire disclosures of the above applications are incorporated by reference herein.

### FIELD

The invention relates to a process for producing an electronic component, and to the electronic component. In particular, the invention relates to the overmolding of an electronics unit and of an electromagnetic actuator of the electronic component with a first plastic and a second plastic to produce a media-tight sheath.

### BACKGROUND

This section provides background information related to the present disclosure which is not necessarily prior art.

Processes for producing electronic components with a media-tight sheath are known from the prior art. For example, WO 2019/162084 A1 discloses such a component in the form of a plug-in connector.

An object is to provide a process for producing an electronic component which makes it possible for production of a media-tight sheath to involve less effort and take less time.

### SUMMARY

This section provides a general summary of the disclosure, and is not a comprehensive disclosure of its full scope or all of its features.

The object is achieved by a process for producing an electronic component which has at least one electromagnetic actuator and an electronics unit. The process also comprises a first overmolding of the electronics unit with a first plastic to produce a first sheath of the electronics unit. The process furthermore comprises a second overmolding of the first sheath together with the electromagnetic actuator to produce a second sheath of the electronics unit and of the electromagnetic actuator. In this respect, the first plastic is injection molded with a lower temperature and/or a lower pressure than the second plastic. The use of two different plastics in the first sheath and the second sheath makes it possible to select a plastic that has ideal properties for its intended task for each sheath.

The first overmolding is carried out such that the first sheath encloses the electronics unit such that, during the second overmolding, the second sheath does not make contact with the electronics unit.

As a result, the temperature-and pressure-sensitive electronics unit is protected by the first sheath against influences, such as temperature and pressure, during the second injection molding of the second plastic. This makes it possible to work in a broader parameter range, primarily in terms of the temperature and pressure parameters, for the injection molding of the second plastic during the second overmolding than would be the case if the electronics unit were subjected to the second overmolding directly. Therefore, the selection of the second plastic for the second overmolding does not need to involve taking the sensitivities of the electronics unit into consideration.

The second overmolding is carried out such that the electromagnetic actuator and the electronics unit with the first sheath are media-tightly enclosed by the second sheath. Since the second sheath with the second plastic ensures the media-tightness of the actuator and of the electronics unit, the first plastic does not need to ensure media-tightness. A plastic which subjects the electronics unit to as little load as possible when the first sheath is being injection molded with the first plastic can therefore be selected for the first sheath. As a result of dividing up the tasks, subjecting the electronics unit to low temperature and pressure loading during the injection molding operation, and ensuring media-tightness, in a first overmolding with a first plastic and a second overmolding with a second plastic, a plastic suitable for its task can be selected for each overmolding. This reduces the number of overmoldings necessary before media-tightness is achieved to two. A media-tight sheath is understood to mean that no media surrounding the sheath, such as water or oils, can pass through the sheath at all.

A configuration provides that at least two electrically conductive pin elements are connected to the electronics unit, in particular by a plate-through connection, before the first overmolding operation. The electronics unit is completely enclosed by the first sheath in the first overmolding operation, wherein the electrically conductive pin elements protrude from the first sheath. In an alternative configuration, the electrically conductive pin elements are connected to the electronics unit, in particular by a plate-through connection, after the first overmolding operation by pressing the pin elements through the first sheath. The pin elements protruding from the first sheath make it possible to supply the electronics unit with current and actuate it. The first sheath protects the pin elements and makes it possible to discharge higher forces into the first sheath than would be the case if a first sheath was not present. As a result, the pin elements can also absorb forces in the second overmolding or during other load-relevant situations.

In a further configuration, the electromagnetic actuator has at least one first cutout and the first sheath is injection molded in the first overmolding into such a mold that the first sheath has at least one second protruding connecting element. The second protruding connecting element can be inserted into the first cutout of the electromagnetic actuator. As an alternative or in addition, the electromagnetic actuator has at least one first protruding connecting element and the first sheath has at least one second cutout, into which the first connecting element of the electromagnetic actuator can be inserted. A connection between the first connecting element and the second cutout and/or a connection between the first cutout and the second connecting element involves an at least partial form fit. The form fit exists in particular with respect to a radial direction of the actuator. By virtue of the form fit, simply connecting the first sheath to the actuator makes it possible to prevent a relative movement of the first sheath in relation to the actuator during the second injection molding. This makes it possible to reduce the number of elements for supporting the first sheath and the actuator and thus for the production to involve less effort and take less time. Moreover, manufacturing tolerances can be minimized.

In a further configuration, the first sheath in the first overmolding is injection molded into such a mold that the first sheath has at least one third cutout. A positioning aid can be inserted into the third cutout. It is alternatively or additionally provided that the first sheath has a third protruding connecting element. The third protruding connecting element can be inserted into the positioning aid. A connection between the positioning aid and the third cutout and/or the third connecting element involves an at least partial form fit. The form fit exists in particular with respect to a radial direction of the actuator. The form fit between the positioning aid and the first sheath makes it possible to precisely position the first sheath. This ensures that the first sheath cannot move relative to the actuator during the second overmolding. Moreover, manufacturing tolerances can be avoided.

In a particularly configuration, the first sheath is connected to the electromagnetic actuator after the first overmolding operation by insertion of the second connecting element into the first cutout and/or by insertion of the first connecting element into the second cutout. As an alternative or in addition, the first sheath is connected to the positioning aid after the first overmolding operation by insertion of the third connecting element into the positioning aid and/or by insertion of the positioning aid into the third cutout. After the first sheath has been connected to the positioning aid, the second overmolding is carried out. The at least partial form-fitting connection between the first sheath and the positioning aid makes it possible also to use higher pressures for the injection molding of the second plastic during the second overmolding than would be the case if the first sheath was not supported. This allows more complex geometries to be filled and means the production takes less time.

The system additionally relates to an electronic component comprising an electromagnetic actuator, an electronics unit surrounded by a first sheath made of a first injection-molded plastic, and a second sheath made of a second injection-molded plastic. The second sheath surrounds the first sheath and the actuator. The first plastic can be injection molded at a lower temperature and/or with a lower pressure than the second plastic. The use of two different plastics in the first sheath and the second sheath makes it possible to select a plastic that has ideal properties for its intended task for each sheath.

The first sheath encloses the electronics unit such that the second sheath does not make direct contact with the electronics unit. The first sheath protects the temperature-and pressure-sensitive electronics unit against influences, such as temperature and pressure, during the second injection molding of the second plastic. This makes it possible to work in a broad parameter range, primarily in terms of the temperature and pressure parameters, for the injection molding of the second plastic during the second overmolding than would be the case if the temperature-and pressure-sensitive electronics unit were subjected to the second overmolding directly. Therefore, the selection of the second plastic for the second injection molding does not need to involve taking the sensitivities of the electronics unit into consideration.

The second sheath media-tightly encloses the electromagnetic actuator and the electronics unit with the first sheath. Since the second sheath with the second plastic ensures the media-tightness of the actuator and of the electronics unit, the first plastic does not need to ensure media-tightness. A plastic which subjects the electronics unit to as little load as possible when the first sheath is being injection molded with the first plastic can therefore be selected for the first sheath. As a result of dividing up the tasks, subjecting the electronics unit to low temperature and pressure loading during the injection molding operation, and ensuring media-tightness, in a first overmolding with a first plastic and a second overmolding with a second plastic, a plastic suitable for its task can be selected for each overmolding. This reduces the number of overmoldings necessary before media-tightness is achieved to two. A media-tight sheath is understood to mean that no media surrounding the sheath, such as water or oils, can pass through the sheath at all.

In a configuration, two electrically conductive pin elements are connected to the electronics unit, wherein the electrically conductive pin elements protrude from the first sheath. The pin elements protruding from the first sheath make it possible to supply the electronics unit with current and/or transmit or receive control signals. The first sheath protects the pin elements and makes it possible to discharge higher forces into the first sheath than would be the case if a first sheath was not present. As a result, the pin elements can also absorb the forces arising during the second overmolding or during other load-relevant situations.

The electromagnetic actuator has at least one first cutout and the first sheath has at least one second protruding connecting element. As an alternative or in addition, the electromagnetic actuator has at least one first protruding connecting element and the first sheath has at least one second cutout. The first connecting element can be connected to the second cutout and/or the first cutout can be connected to the second connecting element such that there is at least a partial form fit. The form fit exists with respect to a radial direction of the actuator. By virtue of the form fit, simply connecting the first sheath to the actuator makes it possible to prevent a relative movement of the first sheath in relation to the actuator during the second injection molding. This makes it possible to reduce the number of elements for supporting the first sheath and the actuator and thus for the production to involve less effort and take less time. Moreover, manufacturing tolerances can be minimized.

The first sheath has at least one third protruding connecting element, which can be inserted into a positioning aid. As an alternative or in addition, the first sheath has at least one third cutout, into which a positioning aid can be inserted, with the result that a connection between the positioning aid and the third connecting element and/or the third cutout involves at least a partial form fit. The form fit exists with respect to a radial direction of the actuator. The form fit between the positioning aid and the first sheath makes it possible to precisely position the first sheath. This ensures that the first sheath cannot move relative to the actuator during the second overmolding.

In a further, configuration, the electronics unit has a circuit board with a Hall sensor, wherein the Hall sensor is arranged closer to a surface of the first sheath than the circuit board or another component on the circuit board is. The Hall sensor makes it possible to ascertain a field strength and use that to draw conclusions as to the presence of a magnet. Such a magnet can be at one end of an actuating unit which moves through a cutout in the actuator. The Hall sensor can therefore determine the position of the magnet and of the actuating element. By positioning the Hall sensor closer to a surface behind which the magnet of the actuating unit is located than the circuit board is or other elements of the circuit board are, the position of the magnets behind the surface can be determined better.

In a configuration, the first plastic has a lower thermal conductivity than the second plastic. During operation of the electromagnetic actuator, heat is generated in the coils of the actuator. This heat is discharged to the direct vicinity, among other things to the second sheath. By selecting a first plastic with a lower thermal conductivity than the second plastic, transport of the waste heat from the coils through the second sheath to the surrounding area of the electric component is ensured and at the same time the transport of heat from the coil through the first sheath to the temperature-sensitive electronics unit is reduced.

In a configuration, the first plastic is a thermoset and/or the second plastic is a thermoplastic. Thermosets can already be injection molded at low temperatures and low pressures and make it possible to overmold the electronics unit with the first sheath made of a thermoset at lower temperatures and pressures than would be the case for other plastics. Although thermoplastics are injection molded with higher pressures and temperatures than thermosets, in exchange they enable media-tight sealing of the actuator and of the first sheath with a single overmolding. Since the temperature-and pressure-sensitive electronics unit is already protected by the first sheath made of a thermoset, the second overmolding with a thermoplastic does not subject the electronics unit to unreasonable loading. Only two overmoldings are therefore needed to media-tightly seal the actuator and the electronics unit, as a result of which the production takes less time and involves less effort.

Further areas of applicability will become apparent from the description provided herein. The description and specific examples in this summary are intended for purposes of illustration only and are not intended to limit the scope of the present disclosure.

### BRIEF DESCRIPTION OF DRAWINGS

The drawings described herein are for illustrative purposes only of selected embodiments and not all possible implementations, and are not intended to limit the scope of the present disclosure.

Further details, advantages and features of the present invention emerge from the description below of exemplary embodiments on the basis of the drawing. In the drawing:

FIG. 1 shows a schematic view of an electronic component according to an exemplary embodiment of the invention,

FIG. 2 shows a schematic view of an electronics unit of the electric components according to the exemplary embodiment of the invention,

FIG. 3 shows a schematic view of the electronics unit with the electronic component according to the exemplary embodiment of the invention with a first sheath, and

FIG. 4 shows a schematic view of the electronic component according to an exemplary embodiment of the invention with a positioning aid during manufacture.

Corresponding reference numerals indicate corresponding parts throughout the several views of the drawings.

### DETAILED DESCRIPTION

Example embodiments will now be described more fully with reference to the accompanying drawings.

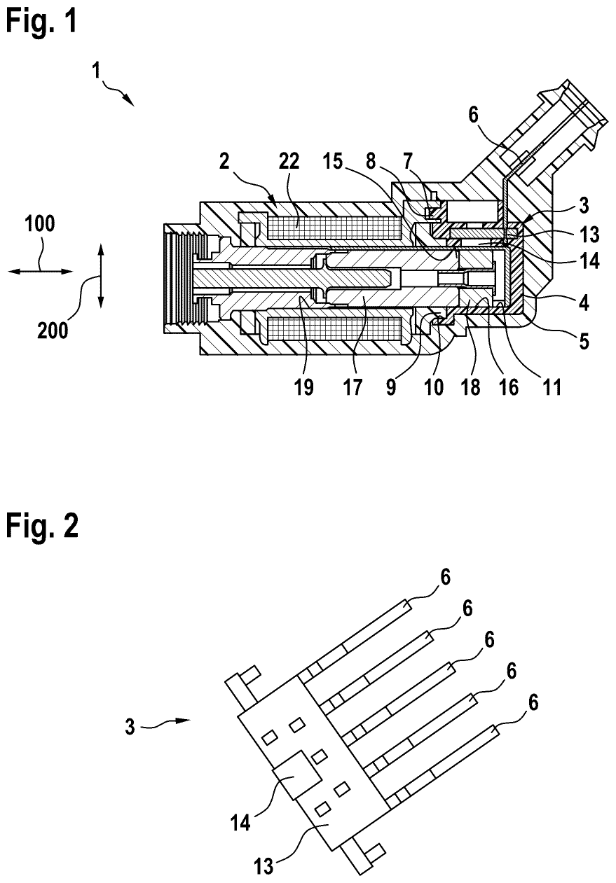

FIG. 1 shows a schematic sectional view of an electric component 1 according to an exemplary embodiment. The electric component 1 comprises an electromagnetic actuator 2, an electronics unit 3, a first sheath 4 and a second sheath 5. The electronics unit 3 comprises a circuit board 13, to which one or more electrically conductive pin elements 6 are connected by a plate-through connection, and a Hall sensor 14. The electronics unit 3 is completely enclosed by the first sheath 4 and is not in direct contact with the second sheath 5. The pin elements 6 protrude from the first sheath 4.

The pin elements 6 may be connected to the circuit board 13 by a plate-through connection before the electronics unit 3 is overmolded with a first plastic. As an alternative, the pin elements 6 may be plugged through the first sheath 4 and the circuit board 13 by a plate-through connection only after the first overmolding operation, in order to be connected to the circuit board 13. Both ways of establishing contact between the pin elements 6 and the circuit board 13 involve the pin elements 6 being supported by the first sheath 4. This allows the pin elements 6 to absorb greater forces than without support by the first sheath 4. In particular, the pin elements 6 can withstand the pressure during a second overmolding of the first sheath 4 with a second sheath 5.

The first sheath 4 is injection molded from a first plastic, in particular a thermoset. Thermosets can already be injection molded at low pressures and temperatures in relation to other plastics and are therefore suitable for a first overmolding of the electronics unit 3. The second sheath 5 is injection molded from a second plastic, in particular a thermoplastic. Thermoplastics can be injection molded only at higher temperatures and pressures than thermosets and enable media-tight sealing of the overmolded elements. Thus, in the exemplary embodiment of FIG. 1, the electronics unit 3 is completely enclosed by the first sheath 4 and the first sheath 4 and the actuator 2 are media-tightly enclosed by the second sheath 5.

Since the first plastic of the first sheath 4 can already be injection molded at a lower temperature and at a lower pressure, the first plastic can be injection molded onto the electronics unit 3 directly, without subjecting the electronics unit 3 to undue loading in the process. The first sheath 4 then protects the electronics unit 3 against external influences. In particular, the first sheath 4 protects the electronics unit 3 against unduly high temperatures and pressures during the second overmolding with the second plastic. The protection of the electronics unit 3 by the first sheath 4 means it is possible to use a plastic that can be injection molded only at higher pressures and temperatures than the first plastic for the second overmolding. As a result, the actuator 2 and the first sheath 4 are subjected to higher loading during the second overmolding than they would be if the actuator 2 and the first sheath were overmolded with a thermoset. However, a second overmolding of the actuator 2 and of the first sheath 4 with a thermoplastic is sufficient to media-tightly seal the actuator 2 and the first sheath 4. For this, the first plastic does not need to ensure media-tight sealing; it is the second plastic in the second overmolding that already does this. It is therefore possible to select a first plastic which does not subject the electronics unit 3 to any undue loading in terms of temperature and pressure during the first overmolding operation. Since only two overmoldings are needed to media-tightly seal the actuator 2 and the electronics unit 3, the production involves less effort and takes less time.

The actuator 2 has coils 22, which generate a magnetic field in order to shift an actuating unit 17 located in the actuator 2. When the magnetic field is being generated, the coils 22 heat up and discharge their heat to the area surrounding them. In order to reduce a transport of heat from the coil 22 to the heat-sensitive electronics unit 3, but still ensure a good transport of heat away from the coil 22 to the area surrounding the electric component 1, the first plastic preferably has a lower thermal conductivity than the second plastic.

The second sheath 5 has at least one first cutout 7, which contains at least one second protruding connecting element 8 of the first sheath 4, and the first cutout 7 and the second connecting element 8 are at least partially form-fittingly connected, in particular with respect to a radial direction of the actuator 2. In this case, a distinctive feature of the connection between the first cutout 7 and the second connecting element 8 is that movement of the first sheath 4 relative to the second sheath 5 during the second overmolding operation is prevented. The second connecting element 8 and the first cutout 7 make it possible to easily plug the second sheath 5 and the first sheath 4 together and thus make it possible to dispense with further auxiliary elements for fixing the first sheath 4 along an axial direction 100 of the actuator 2 and the second sheath 5. This means the production takes less time and involves less effort.

Similarly, the second sheath 5 has a first protruding connecting element 9, which is inserted in a second cutout 10 of the first sheath 4, and the first connecting element 9 and the second cutout 10 are at least partially form-fittingly connected. In this case, a distinctive feature of the connection between the second cutout 10 and the first connecting element 9 is that movement of the first sheath 4 relative to the second sheath 5 during the second overmolding operation is prevented, in particular with respect to the radial direction 200 and/or the axial direction 100. The first connecting element 9 and the second cutout 10 make it possible to easily plug the second sheath 5 and the first sheath 4 together, in particular in the axial direction 100, and thus make it possible to dispense with further auxiliary elements for fixing the first sheath 4 and the second sheath 5. This means the production takes less time and involves less effort.

The actuating unit 17, which can be moved by the actuator 2, has a magnet 18 at one end. The first sheath 4 has a magnet cutout 16, into which the magnet 18 of the actuating unit 17 can be inserted. The magnet cutout 16 has a surface 15. The Hall sensor 14 is arranged closer to the surface 15 than the circuit board 13 or another component on the circuit board 13 is. As a result of this arrangement, it is possible to better measure the field strength of the magnetic field, and thus determine the position of the magnet 18 and of the actuating unit 17, than if the circuit board 13 was still between the Hall sensor 14 and the surface 15.

FIG. 2 shows a schematic view of the electronics unit 3. The electronics unit 3 comprises at least one circuit board 13 and a Hall sensor 14. In the example shown, five electrically conductive pin elements 6 are electrically connected to the circuit board 13, in particular by a plate-through connection. The pin elements 6 supply current to the circuit board 13 and/or serve to exchange data with the circuit board 13. The Hall sensor 14 is electrically connected to the circuit board 13, with the result that the measured values from the Hall sensor 14 can be transmitted to the circuit board 13.

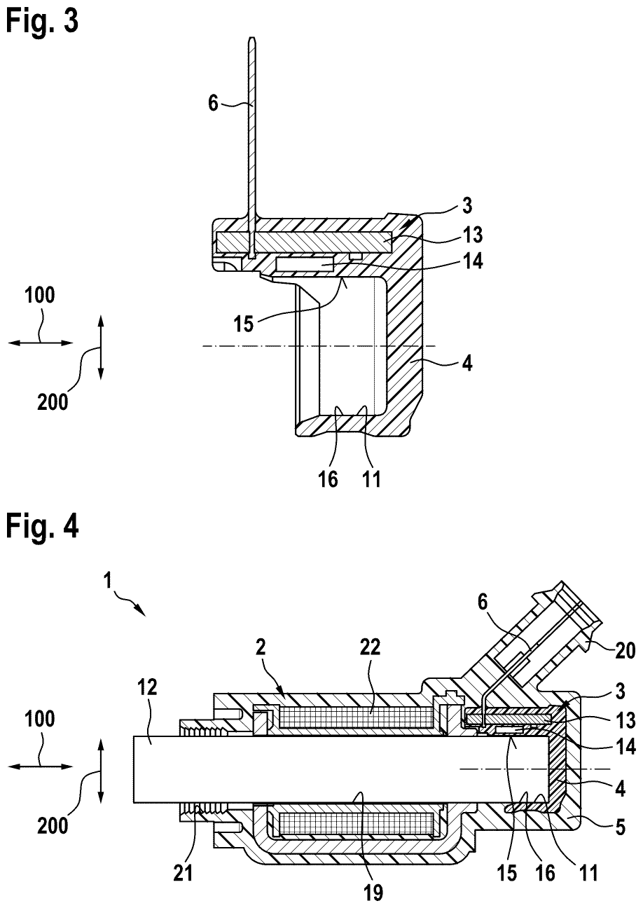

FIG. 3 shows a schematic view of the electronics unit 3 with the first sheath 4. Contact between the pin elements 6 and the circuit board 13, as shown in FIG. 2, can be established before a first overmolding of the electronics unit 3. As an alternative, the pin elements 6 can be plugged through the first sheath 4 and through the circuit board 13 after the first overmolding of the electronics unit 3. In both versions of the connection between the pin elements 6 and the circuit board 13, before or after the first overmolding, the pin elements 6 are supported by the first sheath 4. This makes it possible to subject the pin elements 6 to greater forces than if the pin elements 6 were not supported by the sheath 4. In particular, the pin elements 6 can withstand a pressure during the second overmolding operation. The first sheath 4 completely encloses the electronics unit 3, with the result that direct contact between the electronics unit 3 and a second sheath 5 is prevented.

The Hall sensor 14 is arranged on the circuit board 13; in particular, the Hall sensor 14 is electrically connected to the circuit board 13. The measured values from the Hall sensor 14 can be transmitted to the circuit board 13 via this electrical connection. The first sheath 4 has a magnet cutout 16, into which a magnet 18 on an actuating unit 17 can be inserted. The actuating unit 17 can be moved by the actuator 2. The movement of the actuating unit 17 causes the magnet 18 to enter and leave the magnet cutout 16. The magnet cutout 16 has a surface 15. The Hall sensor 14 is arranged closer to the surface 15 than the circuit board 13 or another component on the circuit board 13 is. As a result of this arrangement, it is possible to better measure the field strength of the magnetic field, and thus determine the position of the magnet 18 and of the actuating unit 17, than if the circuit board 13 was still between the Hall sensor 14 and the surface 15.

The first sheath 4 has a third cutout 11 for positioning and for fixing this position. The third cutout 11 is arranged such that a positioning unit 12 can be inserted into the third cutout 11, in particular in the axial direction 100, and there is at least a partial form fit between the positioning unit 12 and the third cutout 11.

FIG. 4 shows a schematic view of the electronic component 1 according to the exemplary embodiment during manufacture. In FIG. 4, the magnet cutout 16 at the same time performs the function of the third cutout 11. Both cutouts 11, 16 coincide to form one cutout 11, 16. This does not need to be the case; the third cutout 11 could be provided at any desired location on the first sheath 4.

After the first overmolding of the electronics unit 3, the electronics unit 3 with the first sheath 4 is positioned on the actuator 2. In this case, the electronics unit 3 and the actuator 2 must be aligned such that, after the second overmolding, the actuating unit 17 can be inserted into the actuator 2 and at the same time the magnet 18 of the actuating unit 17 can be inserted into the magnet cutout 16. In order to ensure the precise positioning of the first sheath 4 relative to the actuator 2, the positioning aid 12 is inserted into the third cutout 11 in the first sheath 4 through the cutout 19 in the actuator 2, as illustrated in FIG. 4. The positioning aid 12 is at least partially form-fittingly connected to the actuator 2 and the third cutout 11, in particular with respect to a radial direction 200. As a result, the actuator 2 and the first sheath 4 are fixed such that, during the second overmolding of the actuator 2 and of the first sheath 4, the first sheath 4 and the actuator 2 do not shift relative to one another. If the second sheath 5 is cooled, or hardened, after the second overmolding, the actuator 2 and the first sheath 4 are connected to one another by the second sheath such that the positioning aid 12 can be drawn out of the third cutout 11 and the actuating unit cutout 19 without the first sheath 4 shifting relative to the actuator 2. After the positioning unit 12 has been removed, the actuating unit 17 is inserted into the actuating unit cutout 19 in the actuator 2 and in the process the magnet 18 is inserted into the magnet cutout 16 without any resistance. The actuating unit can then be moved freely in the axial direction 100 by the actuator 2.

During the second overmolding, the actuator 2 and the first sheath 4 are media-tightly enclosed. In this case, the pin elements 6 are not completely enclosed by the second sheath 5, with the result that electrical contact can still be established with the pin elements 6. The second sheath 5 has the form of a plug-in connector 20 around the pin elements 6, this form enabling a plug-in connection to a mating plug-in connector (not illustrated here). Thus, for example, the pin elements 6 can establish electrical contact with an external unit (not shown). Current can be supplied to the electronics unit 3 by the external unit via the pin elements 6. Similarly, data can be exchanged between the external unit and the electronics unit 3.

Furthermore, the second sheath 5 has an access cutout 21, which is coaxial with the actuating unit cutout 19 and is connected to the actuating unit cutout 19. The access cutout 21 in the second sheath 5 makes it possible to remove the positioning aid 12 from the actuating unit cutout 19 and the third cutout 11. Similarly, the actuating unit 17 with the magnet 18 can be inserted into the actuating unit cutout 19 and into the magnet cutout 16 through the access cutout 19. In addition, the second sheath 5 can have further functional features; thus, it is possible to provide one or more internal threads for screw connections and surfaces for establishing contact with surfaces of other elements in the vicinity.

In addition to the above written description of the invention, reference is hereby explicitly made to the diagrammatic illustration of the invention in FIGS. 1 to 4 for additional disclosure thereof.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

### LIST OF REFERENCE SIGNS

1 Electronic component
2 Electromagnetic actuator
3 Electronics unit
4 First sheath
5 Second sheath
6 Electrically conductive pin elements
7 First cutout
8 Second protruding connecting element
9 First protruding connecting element
10 Second cutout
11 Third cutout
12 Positioning aid
13 Circuit board
14 Hall sensor
15 Surface
16 Magnet cutout
17 Actuating unit
18 Magnet
19 Actuating unit cutout
20 Plug-in connector
21 Access cutout
22 Coil
100 Axial direction
200 Radial direction

1. A process for producing an electronic component, which has at least one electromagnetic actuator and an electronics unit, wherein the process comprises:
a first overmolding of the electronics unit with a first plastic to produce a first sheath of the electronics unit, and
a second overmolding of the first sheath together with the electromagnetic actuator with a second plastic to produce a second sheath of the electronics unit and of the electromagnetic actuator, wherein
the first plastic is injection molded with a lower temperature and/or a lower pressure than the second plastic;
the first overmolding is carried out such that the first sheath encloses the electronics unit such that, during the second overmolding, the second sheath does not make contact with the electronics unit, and
the second overmolding is carried out such that the electromagnetic actuator and the electronics unit with the first sheath are media-tightly enclosed by the second sheath.

2. The process as claimed in claim 1, wherein at least two electrically conductive pin elements are connected to the electronics unit, by a plate-through connection, before the first overmolding operation and the electronics unit is completely enclosed by the first sheath in the first overmolding operation, wherein the electrically conductive pin elements protrude from the first sheath, or the electrically conductive pin elements are connected to the electronics unit, by a plate-through connection, after the first overmolding operation by pressing the pin elements through the first sheath.

3. The process as claimed in claim 1, wherein the electromagnetic actuator has at least one first cutout and the first sheath in the first overmolding is injected into such a mold that the first sheath has at least one second protruding connecting element, which can be inserted into the at least one first cutout of the electromagnetic actuator, and/or the electromagnetic actuator has at least one first protruding connecting element and the first sheath has at least one second cutout, into which the first connecting element of the electromagnetic actuator can be inserted, with the result that a connection between the first connecting element and the second cutout and/or a connection between the first cutout and the second connecting element involves an at least partial form fit.

4. The process as claimed in claim 1, wherein the first sheath in the first overmolding is injected into such a mold that the first sheath has at least one third cutout, into which a positioning aid can be inserted, and/or that the first sheath has a third protruding connecting element, which can be inserted into the positioning aid, with the result that a connection between the positioning aid and the third cutout and/or the third connecting element involves an at least partial form fit.

5. The process as claimed in claim 3, wherein the first sheath is connected to the electromagnetic actuator after the first overmolding operation by insertion of the second connecting element into the first cutout and/or by insertion of the first connecting element into the second cutout, and/or the first sheath is connected to the positioning aid after the first overmolding operation by insertion of the third connecting element into the positioning aid and/or by insertion of the positioning aid into the third cutout the first overmolding and then the second overmolding is carried out.

6. An electronic component comprising:
an electromagnetic actuator;
an electronics unit, which is surrounded by a first sheath made of a first injection-molded plastic, and
a second sheath which is made of a second injection-molded plastic and surrounds the first sheath and the actuator, wherein
the first plastic can be injection molded at a lower temperature and/or with a lower pressure than the second plastic;
the first sheath encloses the electronics unit such that the second sheath does not make direct contact with the electronics unit, and
the second sheath media-tightly encloses the electromagnetic actuator and the electronics unit with the first sheath.

7. The electronic component as claimed in claim 6, wherein at least two electrically conductive pin elements are connected to the electronics unit, wherein the electrically conductive pin elements protrude from the first sheath.

8. The electronic component as claimed in claim 6, wherein the electromagnetic actuator has at least one first cutout and the first sheath has at least one second protruding connecting element, and/or the electromagnetic actuator has at least one first protruding connecting element and the first sheath has at least one second cutout, wherein the first connecting element can be connected to the second cutout and/or the first cutout can be connected to the second connecting element such that there is at least a partial form fit.

9. The electronic component as claimed in claim 6, wherein the first sheath has at least one third protruding connecting element, which can be inserted into a positioning aid, and/or the first sheath has at least one third cutout, into which a positioning aid can be inserted, with the result that a connection between the positioning aid and the third connecting element and/or the third cutout involves at least a partial form fit.

10. The electronic component as claimed in claim 6, wherein the electronics unit has a circuit board with a Hall sensor, and wherein the Hall sensor is arranged closer to a surface of the first sheath than the circuit board or another component on the circuit board is.

11. The electronic component as claimed in claim 6, wherein the first plastic has a lower thermal conductivity than the second plastic, and/or wherein the first plastic is a thermoset and/or wherein the second plastic is a thermoplastic.
